(19) United States
(12) Patent Application Publication
(10) Pub. No.: US 2011/0267745 A1
(43) Pub. Date: Nov. 3, 2011

(54) ILLUMINANT HUMAN INTERFACE DEVICE

(75) Inventors: Shan Liang Cheng, Taipei (TW); Chao Yi Chen, Taipei (TW); Min Hua Chen, Taipei (TW); Li Lun Liu, Taipei (TW)

(73) Assignee: GETAC TECHNOLOGY CORPORATION, Hsinchu (TW)

(21) Appl. No.: 12/892,751

(22) Filed: Sep. 28, 2010

Related U.S. Application Data
(60) Provisional application No. 61/329,000, filed on Apr. 28, 2010.
(60) Provisional application No. 61/331,062, filed on May 4, 2010.

(30) Foreign Application Priority Data
Jul. 9, 2010 (CN) CN201010222063.3

(51) Int. Cl. H05K 7/14

(52) U.S. Cl. 361/679.01

(57) ABSTRACT

The present invention relates to an illuminant human interface device, and more particularly to a housing structure assembly. A housing structure assembly for carrying an input device includes a housing structure, a light source and an input device. The housing structure includes an input device carrying area and a light-transmissive layer. The light-transmissive layer has a light incident plane and a light exit plane, and the light exit plane is located in the input device carrying area. The light source is adjacent to the light incident plane, and the light source emits a light ray. The light ray enters the light-transmissive layer through the light incident plane and then exits the housing structure through the light exit plane. The input device is located on the light exit plane. The housing structure for carrying the input device provides a backlight for the input device after being combined with the light source, thus reducing the repair and replacement costs of the input device.

### BACKGROUND OF THE INVENTION

1. Field of the Invention

The present invention relates to an illuminant human interface device, and more particularly to a light-transmissive housing structure and an assembly of the light-transmissive housing structure and an input device.

2. Related Art

Generally speaking, for achieving a diversity of keyboards applied in laptop computers or mobile phones, a light-emitting input device has become a favorite trend. Taking a laptop computer as an example, the laptop computer equipped with a light-emitting keyboard is now available in the market. The laptop computer equipped with the light-emitting keyboard has a switch for controlling the brightness of the light rays emitted by the light-emitting keyboard, which enables the user to adjust the luminous quantity of the light-emitting keyboard at will in different situations and environments.

In addition, the laptop computer equipped with the light-emitting keyboard may have a light source sensor, and light source sensor is connected to a switch of the light-emitting keyboard. The light source sensor may control to turn on the switch of the light-emitting keyboard when sensing that the ambient brightness is smaller than a standard value, or control to turn off the switch of the light-emitting keyboard when sensing that the ambient brightness is greater than the standard value.

Generally, the conventional light-emitting keyboard structure is composed of a base plate, a membrane circuit board, an elastic element, a keycap, a light source, and a light guiding plate. The light guiding plate is placed on the base plate and the membrane circuit board, and the light source is placed between the membrane circuit board and the light guiding plate. The light ray emitted by the light source is guided by the light guiding plate, such that the keycap generates a light-emitting effect.

However, the conventional light-emitting keyboard structure has the light-emitting mechanism built therein, in which the light-emitting mechanism is composed of the light source and the light guiding plate. Therefore, the cost of the conventional light-emitting keyboard is much higher than the traditional keyboard without the light-emitting function. For example, presently, the price of the light-emitting keyboard structure is around a double of the traditional keyboard without the light-emitting function. If the input device needs repair and replacement, usually, the light-emitting keyboard and the built-in light-emitting mechanism are replaced together, so the repair cost or replacement cost is increased.

### SUMMARY OF THE INVENTION

In view of the above problem, the present invention is a housing structure for carrying an input device and an assembly of the housing structure and the input device, so as to solve the problem of high repair cost or replacement cost caused by the repair or replacement of the light-emitting keyboard.

The housing structure assembly for carrying an input device according to an embodiment of the present invention has a housing structure. The housing structure has an input device carrying area for carrying an input device, and the input device may be a mechanical keyboard or a touch panel. The housing structure comprises a light-transmissive layer. The material of the light-transmissive layer may be acrylic or polycarbonate. The light-transmissive layer has a light incident plane and a light exit plane, and the light exit plane is located in the input device carrying area. After a light ray enters the light-transmissive layer through the light incident plane, the light ray is scattered in the light-transmissive layer. Then, the light ray comes out of the housing structure through the light exit plane to serve as a backlight of the input device.

The housing structure assembly for carrying the input device according to an embodiment of the present invention further comprises a light reflecting layer. The light-transmissive layer has a bottom surface, and the bottom surface is opposite to the light exit plane and forms an acute angle with the light exit plane. The light incident plane connects the light exit plane and the bottom surface and faces the bottom surface. The light reflecting layer covers the bottom surface, i.e., is located beneath the light-transmissive layer. In addition, the light ray may be reflected to the light exit plane by the light reflecting layer covering the bottom surface of the light-transmissive layer, and uniformly scattered on the light exit plane.

The housing structure assembly for carrying the input device according to an embodiment of the present invention further comprises a light reflecting layer. The light-transmissive layer has a bottom surface, and the bottom surface is opposite to the light exit plane and may also be parallel to the light exit plane. The light incident plane connects the light exit plane and the bottom surface and faces the bottom surface. The light reflecting layer covers the bottom surface, i.e., is located beneath the light-transmissive layer. In addition, energy of the light ray exiting through the light exit plane may be enhanced by the light reflecting layer covering the bottom surface of the light-transmissive layer.

The housing structure according to an embodiment of the present invention comprises a light shielding layer. The light shielding layer surrounds the light-transmissive layer and exposes the light exit plane. The light shielding layer and the light-transmissive layer may be combined in a manner of plastic double ejection, close fit or In-Mold Roller (IMR) injection molding.

The housing structure according to an embodiment of the present invention comprises a light shielding layer. The light shielding layer may also be laminated on the light-transmissive layer, and the light shielding layer has a through hole exposing the light exit plane. The through hole may be filled up with a transparent plastic material. The light shielding layer and the light-transmissive layer may be combined in a manner of plastic double ejection, hot melt or IMR injection molding.

Furthermore, the housing structure assembly for carrying the input device according to an embodiment of the present invention further comprises a light source and an input device. The light source is adjacent to the light incident plane, and the light source emits a light ray. The light ray enters the light-transmissive layer through the light incident plane and then exits the housing structure through the light exit plane. The input device is located on the light exit plane.

In the housing structure assembly for carrying the input device according to an embodiment of the present invention, the input device is a mechanical keyboard.

In the housing structure assembly for carrying the input device according to an embodiment of the present invention, the input device is a touch panel.

According to the housing structure assembly for carrying the input device of the above embodiments of the present invention, since the housing structure having the light-transmissive layer may provide a backlight function for the input device after being combined with the light source, the input device does not need a built-in backlight module. Therefore, the housing structure having the light-transmissive layer may reduce the manufacturing cost of the input device and the repair and replacement costs.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1A is a sectional structure view of a housing structure assembly for carrying an input device according to a first embodiment of the present invention;

FIG. 1B a sectional structure view of another mechanical keyboard embodiment of the housing structure assembly for carrying the input device according to the first embodiment of the present invention;

FIG. 1C is a top view of the housing structure in FIGS. 1A and 1B;

FIG. 2A is a sectional structure view of a housing structure assembly for carrying an input device according to a second embodiment of the present invention;

FIG. 2B is a sectional structure view of another mechanical keyboard embodiment of the housing structure assembly for carrying the input device according to the second embodiment of the present invention;

FIG. 2C is a top view of the housing structure in FIGS. 2A and 2B;

FIG. 3A is a sectional structure view of a housing structure assembly for carrying an input device according to a third embodiment of the present invention;

FIG. 3B is a sectional structure view of another mechanical keyboard embodiment of the housing structure assembly for carrying the input device according to the third embodiment of the present invention;

FIG. 4 is a sectional structure view of a housing structure assembly for carrying an input device according to a fourth embodiment of the present invention;

FIG. 5 is a sectional structure view of a housing structure assembly for carrying an input device according to a fifth embodiment of the present invention;

FIG. 6 is a sectional structure view of a housing structure assembly for carrying an input device according to a sixth embodiment of the present invention; and

FIG. 7 is a sectional structure view of a housing structure assembly for carrying an input device according to a seventh embodiment of the present invention.

### DETAILED DESCRIPTION OF THE INVENTION

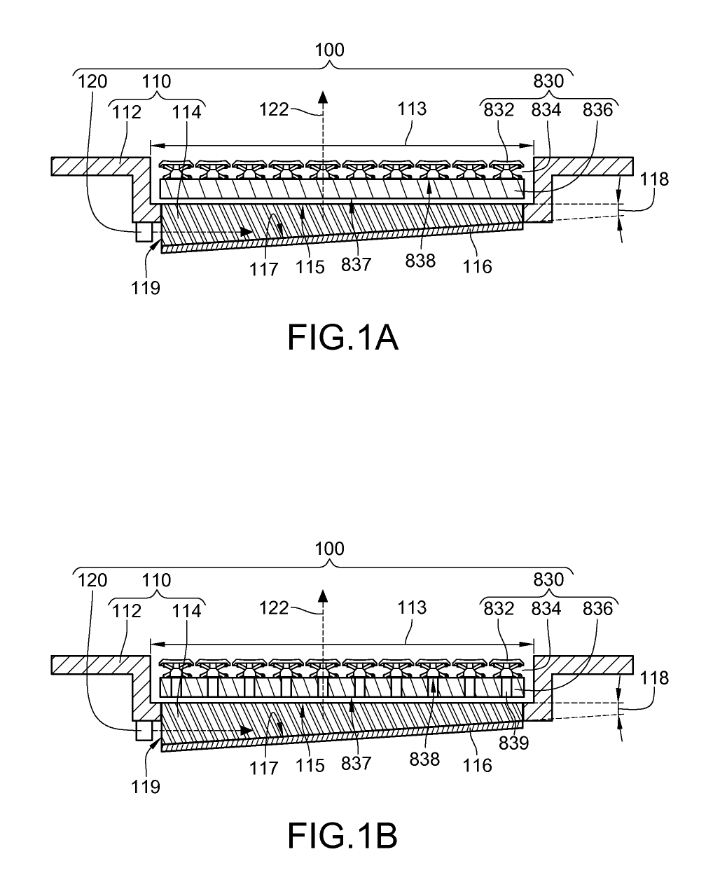

FIGS. 1A and 1B are schematic views of a housing structure assembly for carrying an input device 100 according to a first embodiment of the present invention. The housing structure assembly for carrying the input device 100 comprises a housing structure 110, a light source 120 and an input device. The light source 120 may be a light-emitting diode (LED).

The housing structure 110 has an input device carrying area 113. The input device is disposed on the housing structure 110 and is disposed in the input device carrying area 113. For the convenience of illustration, the input device of this embodiment is, for example, a mechanical keyboard 830.

The mechanical keyboard 830 comprises multiple keycaps 832, multiple actuation elements 834 and a carrier plate 836. The carrier plate 836 has a carrier top surface 838 and a carrier bottom surface 837 opposite to the carrier top surface 838. The actuation elements 834 are assembled on the carrier top surface 838. Each keycap 832 is assembled with one actuation element 834. The mechanical keyboard 830 is configured in the input device carrying area 113, and the carrier bottom surface 837 of the carrier plate 836 in the mechanical keyboard 830 is connected to the housing structure 110 of the carrying input device. In addition, the material of the carrier plate 836 is a light-transmissive material, which allows the light ray to pass, for example the carrier plate 836 in FIG. 1A. Or, the carrier plate 836 may have a plurality of irregular through holes 839 penetrating the carrier plate 836 from the carrier top surface 838 to the carrier bottom surface 837, which allows the light ray to pass, for example the carrier plate 836 in FIG. 1B.

Furthermore, the housing structure 110 further comprises a light-transmissive layer 114, and the mechanical keyboard 830 is located on the light-transmissive layer 114. The material of the light-transmissive layer 114 may be acrylic or polycarbonate. The light-transmissive layer 114 has a light incident plane 119, a light exit plane 115 and a bottom surface 117. The light exit plane 115 is located in the input device carrying area 113. The bottom surface 117 is opposite to the light exit plane 115 and forms an acute angle 118 with the light exit plane 115. Moreover, the light incident plane 119 connects the light exit plane 115 and the bottom surface 117 and faces the bottom surface 117.

The light source 120 is adjacent to the light incident plane 119. When the light source 120 emits a light ray 122, the light ray 122 enters the light-transmissive layer 114 through the light incident plane 119, and is scattered in the light-transmissive layer 114. Finally, the light ray 122 exits the housing structure 110 through the light exit plane 115. Since the mechanical keyboard 830 is disposed in the input device carrying area 113, the light ray 122 exiting the housing structure 110 through the light exit plane 115 may serve as a backlight of the mechanical keyboard 830. FIG. 1C is a top view of the housing structure 110 in FIGS. 1A and 1B. Referring to FIG. 1C, the housing structure 110 may further comprise a light shielding layer 112. The light shielding layer 112 surrounds the light-transmissive layer 114 and exposes the light exit plane 115. The light shielding layer 112 and the light-transmissive layer 114 may be combined in a manner of double ejection or close fit. In addition, the light shielding layer 112 and the light-transmissive layer 114 may be combined in a manner of IMR, i.e., the light shielding layer 112 and the light-transmissive layer 114 are made of the transparent plastic, and is formed by injecting the plastic into a mould by a plastic injection molding machine. At the same time, the membrane is transferred on the outer surface of the light shielding layer 112, thereby blocking the light ray from exiting the light shielding layer 112.

The light ray 122 enters the light-transmissive layer 114 through the light incident plane 119, then reaches the light exit plane 115 from the light-transmissive layer 114, and finally comes out. The energy of the light ray 122 is attenuated and scattered in this course, and a part of the light ray 122 may exit the housing structure 110 through the bottom surface 117. Therefore, the housing structure assembly for carrying the input device 100 may further comprise a light reflecting layer 116, and the light reflecting layer 116 covers the bottom surface 117 from below. The light reflecting layer 116 covering the bottom surface 117 of the light-transmissive layer 114 reflects a part of the light ray 112 originally exiting through the bottom surface 117 back, so as to enhance the energy of the light ray 122 exiting the light exit plane 115. Furthermore, the bottom surface 117 of the light-transmissive layer 114 may have a micro recess or is printed with an optical ink dot. Both the micro recess and the printing of the optical ink dot may enhance the part of light ray 112 reflected to the bottom surface 117, thereby improving the ratio of the light ray 122 exiting the light exit plane 115.

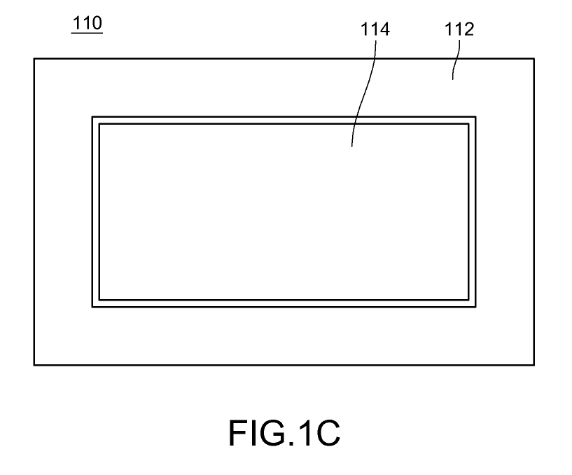

FIGS. 2A and 2B are schematic views of a housing structure assembly for carrying an input device 200 according to a second embodiment of the present invention. The housing structure assembly for carrying the input device 200 comprises a housing structure 210, a light source 220 and an input device. The light source 220 may be an LED.

The housing structure 210 has an input device carrying area 213. The input device is disposed on the housing structure 210, and is disposed in the input device carrying area 213. For the convenience of illustration, the input device of this embodiment is, for example, a mechanical keyboard 830. Since the structure of the second embodiment is substantially the same as that of the first embodiment, the details of the same parts are not described again, and only the part of the second embodiment that differs from the first embodiment is illustrated herein.

The difference between this embodiment and the first embodiment lies in that the housing structure 210 further comprises a light-transmissive layer 214, and the light-transmissive layer 214 has a light incident plane 219, a light exit plane 215 and a bottom surface 217. The light exit plane 215 is located in the input device carrying area 213. The bottom surface 217 is opposite to the light exit plane 215 and parallel to the light exit plane 215. In addition, the light incident plane 219 connects the light exit plane 215 and the bottom surface 217.

FIG. 2C is a top view of the housing structure 210 in FIGS. 2A and 2B. Referring to FIG. 2C, since the relative position of the light shielding layer 212 and the light-transmissive layer 214 of the housing structure 210 in the second embodiment is the same as that of the first embodiment, the details will not be described again herein.

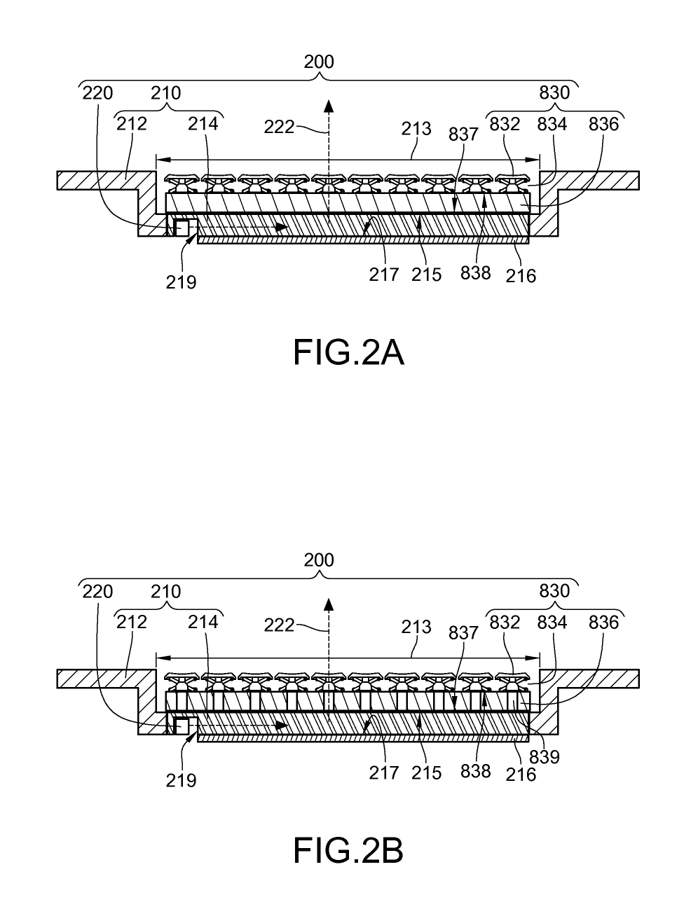

FIGS. 3A and 3B are schematic views of a housing structure assembly for carrying an input device 300 according to a third embodiment of the present invention. The housing structure assembly for carrying the input device 300 comprises a housing structure 310, a light source 320 and an input device. The light source 320 may be an LED.

The housing structure 310 has an input device carrying area 313. The input device is disposed on the housing structure 310, and is disposed in the input device carrying area 313. For the convenience of illustration, the input device of this embodiment is, for example, a mechanical keyboard 830. Since the structure of the third embodiment is substantially the same as that of the first embodiment, the details of the same parts are not described again, and only the part of the third embodiment that differs from the first embodiment is illustrated herein

The difference between this embodiment and the first embodiment lies in that the housing structure 310 further comprises a light-transmissive layer 314, and the light-transmissive layer 314 has a light incident plane 319, a light exit plane 315 and a bottom surface 317. The light exit plane 315 is located in the input device carrying area 313. The bottom surface 317 is opposite to the light exit plane 315 and parallel to the light exit plane 315. In addition, the light incident plane 319 connects the light exit plane 315 and the bottom surface 317. The housing structure 310 further comprises a light shielding layer 312, which is laminated on the light-transmissive layer 314, and the light shielding layer 312 has a through hole 318 exposing the light exit plane 315. The through hole 318 may also be filled up with a transparent plastic material. The light shielding layer 312 and the light-transmissive layer 314 may be combined in a manner of double ejection or hot melt.

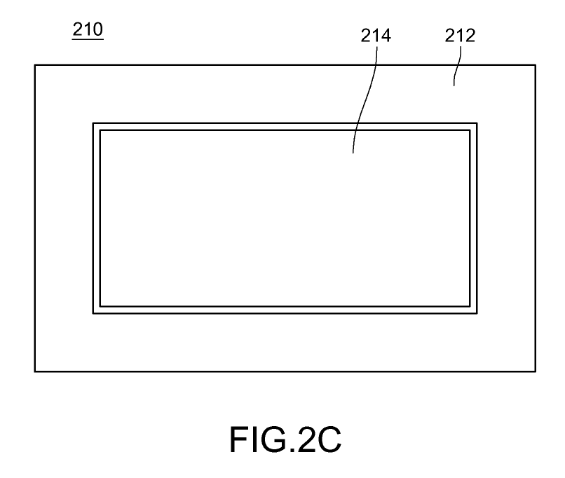

FIG. 4A is a schematic view of a housing structure assembly for carrying an input device 400 according to a fourth embodiment of the present invention. The housing structure assembly for carrying the input device 400 comprises a housing structure 410, a light source 420 and an input device. The light source 420 may be an LED. In this embodiment, the input device is a touch panel 930. The structure of this embodiment is substantially the same as that of the first embodiment, while the difference lies in that the input device of this embodiment is the touch panel 930 instead of the mechanical keyboard 830, so the details of the structure will not be described again herein.

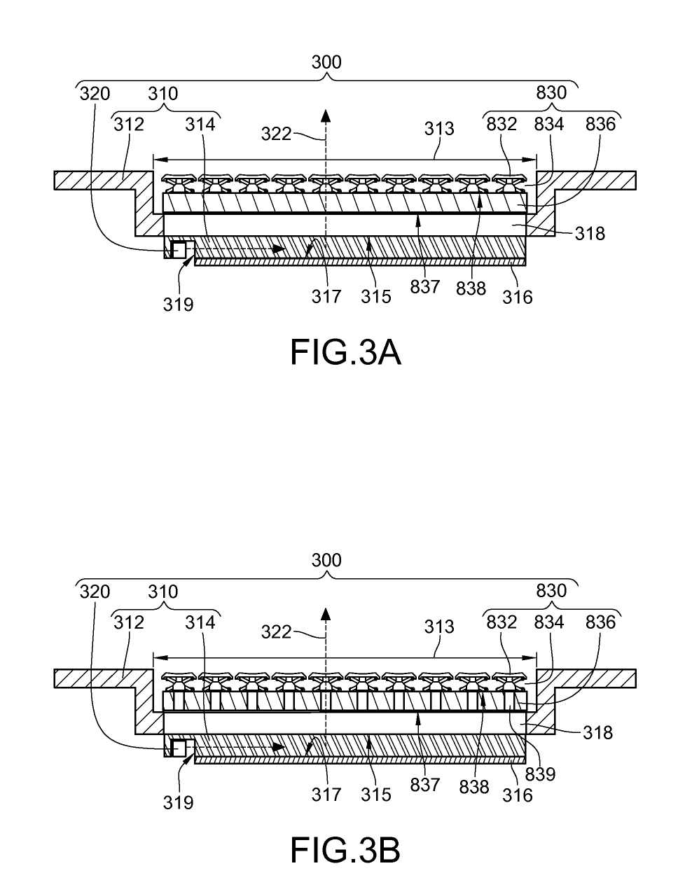

FIG. 5 is a schematic view of a housing structure assembly for carrying an input device 500 according to a fifth embodiment of the present invention. The housing structure assembly for carrying the input device 500 comprises a housing structure 510, a light source 520 and an input device. The light source 520 may be an LED. In this embodiment, the input device is a touch panel 930. The structure of this embodiment is substantially the same as that of the second embodiment, while the difference lies in that the input device of this embodiment is the touch panel 930 instead of the mechanical keyboard 830, so the details of the structure will not be described again herein.

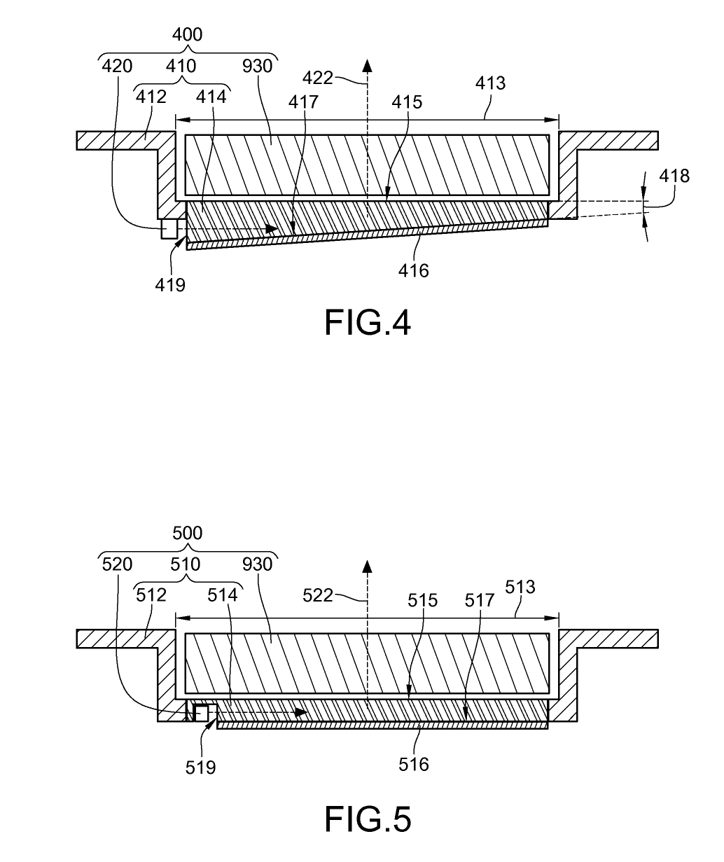

FIG. 6 is a schematic view of a housing structure assembly for carrying an input device 600 according to a sixth embodiment of the present invention. The housing structure assembly for carrying the input device 600 comprises a housing structure 610, a light source 620 and an input device. The light source 620 may be an LED. In this embodiment, the input device is a touch panel 930. The structure of this embodiment is substantially the same as that of the third embodiment, while the difference lies in that the input device of this embodiment is the touch panel 930 instead of the mechanical keyboard 830, so the details of the structure will not be described again herein.

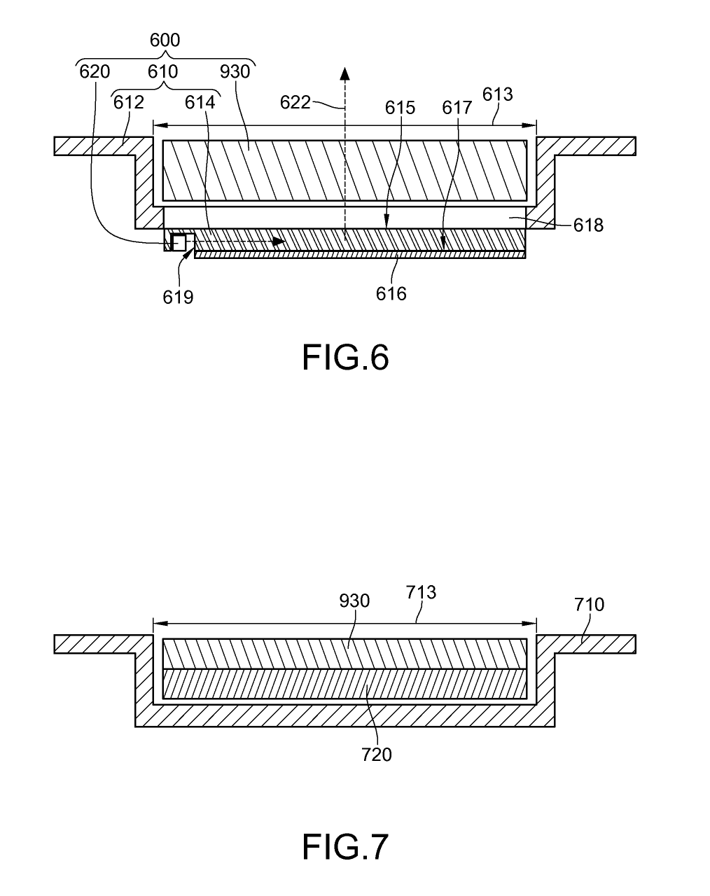

FIG. 7 is a schematic view of a housing structure assembly for carrying an input device 700 according to a seventh embodiment of the present invention. The housing structure assembly for carrying the input device 700 comprises a touch panel 930, a backlight module 720 and a housing structure 710. The touch panel 930 and the backlight module 720 are laminated, and the touch panel 930 is located above the backlight module 720. The housing structure 710 has an input device carrying area 713 for carrying the touch panel 930 and the backlight module 720. The touch panel 930 and the backlight module 720 are located in the input device carrying area 713. The backlight module 720 is formed by a light-transmissive layer, a light shielding layer, a reflecting layer and a light source. The light-transmissive layer has a light incident plane and a light exit plane. The light shielding layer has a light exit hole. The light source provides a light ray that enters the light-transmissive layer, and the light ray is scattered in the light-transmissive layer and then exits through the light exit plane. The light ray exiting through the light exit plane passes through the light exit hole of the light shielding layer to the touch panel 930. The light ray is the backlight of the touch panel 930. The reflecting layer may be laminated beneath the light-transmissive layer, for enhancing the strength of the backlight.

In the housing structure assembly for carrying the input device according to the embodiments of the present invention, the housing structure has a light-transmissive layer. Since the housing structure having the light-transmissive layer may provide a backlight function for the input device after being combined with the light source, the input device does not need an extra backlight module, thus reducing the manufacturing cost of the input device and the repair cost.

What is claimed is:

1. A housing structure assembly for carrying an input device, comprising a housing structure, wherein the housing structure has an input device carrying area, and the housing structure comprises a light-transmissive layer, the light-transmissive layer has a light incident plane and a light exit plane, the light exit plane is located in the input device carrying area, and after a light ray enters the light-transmissive layer through the light incident plane, the light ray exits the housing structure through the light exit plane to serve as a backlight of the input device.

2. The housing structure assembly for carrying the input device according to claim 1, further comprising a light reflecting layer, wherein the light-transmissive layer has a bottom surface, the bottom surface is opposite to the light exit plane and forms an acute angle with the light exit plane, the light incident plane connects the light exit plane and the bottom surface and faces the bottom surface, and the light reflecting layer covers the bottom surface.

3. The housing structure assembly for carrying the input device according to claim 1, further comprising a light reflecting layer, wherein the light-transmissive layer has a bottom surface, the bottom surface is opposite to the light exit plane and parallel to the light exit plane, the light incident plane connects the light exit plane and the bottom surface, and the light reflecting layer covers the bottom surface.

4. The housing structure assembly for carrying the input device according to claim 1, wherein the housing structure comprises a light shielding layer, and the light shielding layer surrounds the light-transmissive layer and exposes the light exit plane.

5. The housing structure assembly for carrying the input device according to claim 1, wherein the housing structure comprises a light shielding layer laminated on the light-transmissive layer, the light shielding layer has a through hole, and the through hole exposes the light exit plane.

6. The housing structure assembly for carrying the input device according to claim 1, wherein the input device is located on the light exit plane, and a light source is disposed adjacent to the light incident plane, the light source emits the light ray, and after the light ray enters the light-transmissive layer through the light incident plane, the light ray exits the housing structure through the light exit plane.

7. The housing structure assembly for carrying the input device according to claim 6, further comprising a light reflecting layer, wherein the light-transmissive layer has a bottom surface, the bottom surface is opposite to the light exit plane and forms an acute angle with the light exit plane, the light incident plane connects the light exit plane and the bottom surface and faces the bottom surface, and the light reflecting layer covers the bottom surface.

8. The housing structure assembly for carrying the input device according to claim 6, further comprising a light reflecting layer, wherein the light-transmissive layer has a bottom surface, the bottom surface is opposite to the light exit plane and parallel to the light exit plane, the light incident plane connects the light exit plane and the bottom surface, and the light reflecting layer covers the bottom surface.

9. The housing structure assembly for carrying the input device according to claim 6, wherein the housing structure comprises a light shielding layer, the light shielding layer surrounds the light-transmissive layer and exposes the light exit plane.

10. The housing structure assembly for carrying the input device according to claim 6, wherein the housing structure comprises a light shielding layer laminated on the light-transmissive layer, the light shielding layer has a through hole, and the through hole exposes the light exit plane.

11. The housing structure assembly for carrying the input device according to claim 6, wherein the input device is a mechanical keyboard.

12. The housing structure assembly for carrying the input device according to claim 6, wherein the input device is a touch panel.
